(19) United States
(12) Patent Application Publication
(10) Pub. No.: US 2026/0097727 A1
(43) Pub. Date: Apr. 9, 2026

(54) FAILURE SIGN DIAGNOSABLE DRIVE DEVICE

(71) Applicant: HITACHI ASTEMO, LTD., Hitachinaka-shi, Ibaraki (JP)

(72) Inventor: Takumi MASUBUCHI, Hitachinaka-shi, Ibaraki (JP)

(73) Assignee: HITACHI ASTEMO, LTD., Hitachinaka-shi, Ibaraki (JP)

(21) Appl. No.: 19/112,733

(22) PCT Filed: Oct. 14, 2022
(86) PCT No.: PCT/JP2022/038342

§ 371 Date: Mar. 18, 2025

(51) Int. Cl. B60R 16/023; B60R 16/03; G01R 31/40

(52) U.S. Cl. CPC B60R 16/0232; B60R 16/03; G01R 31/40

(57) ABSTRACT

Provided is a drive device capable of diagnosing a failure sign, the drive device having functions of diagnosing the failure sign of a power device; performing load drive control by restricting operation of the power device with the failure sign or by excluding the power device; and suppressing shortening of a replacement cycle of the power device. A drive device 100 includes power devices 1a to 1f that drive a load, characteristic sensors 2a to 2f that detect characteristics of the power devices 1a to 1f, respectively, a sensing result holder 3 that holds detection results acquired by the characteristic sensors 2a to 2f in time series, control signal change units 4 and 5 that each detect a failure sign of each of the power devices 1a to 1f from the detection results in the sensing result holder 3 and output a control change signal, and a drive controller 10 that controls drive of the power devices 1a to 1f. When detecting the failure sign of each of the power devices 1a to 1f based on a control threshold to detect the failure sigh of each of the power devices 1a to 1f, the control signal change units 4 and 5 each output a control change signal 20 to the drive controller 10 to drive a load 200 using the power devices 1a to 1f excluding the power devices 1a to 1f detected.

### TECHNICAL FIELD

The present invention relates to a drive device including an inverter for driving a load such as a motor.

### BACKGROUND ART

Automotive semiconductor components are generally required to have more strict reliability than consumer products, and each semiconductor Supplier performs mass production after guaranteeing reliability for automobiles.

Examples of the guarantee include a guarantee of a 10 year use as an automobile or a guarantee of travel up to 200,000 kilometers. These guarantees include an idea unique to each automobile manufacturer, and an operating time of a semiconductor component per day is assumed to be several hours.

In the automobile industry, automatic driving technology and advanced driving support technology are actively developed. When automated driving level 4 or higher is put into practical use, operation of a driver becomes unnecessary, and thus driving and all other operations are expected to be performed by a system mounted on a vehicle.

Besides the technical development, car sharing is considered to be applied and expanded in the future in terms of services, and an operation form of sharing one automotive with a plurality of users for effectively using an idle time of the one automotive is also considered to be active in the future.

The situation described above has led development in a technique for predicting the life and failure arrival time of the semiconductor component to improve reliability of the semiconductor component.

PTL 1 describes a technique of: calculating a difference between a previous measurement value and a current measurement value of a sensor attached to a power converter; obtaining intermediate data by variably changing a plurality of past differences; and calculating a damage level of the power converter based on the intermediate data. The technique described in PTL 1 causes a warning signal to be output when the damage level exceeds a damage threshold, the warning signal indicating that failure may occur soon.

PTL 2 describes a technique of acquiring a current value when it is determined that a power conversion device has reached a specific operation state, and determining a failure sign based on the acquired current value.

### CITATION LIST

### Patent Literature

PTL 1: JP 2020-141465 A
PTL 2: JP 6184335

### SUMMARY OF INVENTION

### Technical Problem

As described above, the current concept of reliability of automotive semiconductor components includes an assumption of an operating time per day. This is because a human operates an automobile as a driver. In the future, when car sharing or fully automatic driving is put into practical use, the operating time is assumed to be close to 24 hours per day particularly in an extreme case assuming automatic delivery or the like.

A life of the semiconductor component, i.e., failure arrival time in such a case is considered to be relatively much earlier than that at present, and may be considered to be as early as about one or two years.

Although even current automotive semiconductor components are designed to have reliability that can withstand use assuming the above-described use for 10 years and travel of 200,000 kilometers, for example, providing a reliability guarantee corresponding to the 24 hour operation as described above is not realistic in terms of feasibility and cost.

Additionally, a functional failure due to a component failure can be fatal in automatic driving, so that the component failure can be desirably grasped before occurrence thereof.

As described above, an age where automatic driving and car sharing are expected to spread is considered to have options for operation of automobiles, the options including performance maintenance by component replacement. Meanwhile, cost due to the component replacement is added.

Thus, any one of reduction in replacement frequency to suppress the cost of the component replacement and reduction in cost of the component itself to be replaced may be a problem to be solved.

It is also considered that when car sharing is widely used and automatic operation is put into practical use in the future, operation time of a semiconductor component per day is expanded to accelerate deterioration of a power device, thereby shortening a replacement cycle. For this reason, it is necessary not only to predict failure at an early stage but also to delay progress of deterioration in consideration of control conditions to suppress shortening of the replacement cycle.

It is an object of the present invention to provide a drive device capable of diagnosing a failure sign, the drive device having functions of diagnosing the failure sign of a power device; performing load drive control by restricting operation of the power device with the failure sign or by excluding the power device; and suppressing shortening of a replacement cycle of the power device.

### Solution to Problem

To achieve the above object, the present invention is configured as follows.

A drive device capable of failure sign diagnosis includes: a plurality of power devices configured to drive a load; a characteristic sensor configured to detect a characteristic of each of the plurality of power devices; a sensing result holder configured to hold detection results of the plurality of power devices in time series, the detection results being acquired by the characteristic sensor; a control signal change unit configured to detect a failure sign of each of the plurality of power devices from the detection results held in time series by the sensing result holder and output a control change signal; and a drive controller configured to control driving of the plurality of power devices, in which the control signal change unit detects a failure sign of each of the plurality of power devices based on a control threshold, and when detecting the failure sign of one or more power devices of the plurality of power devices, the control signal change unit outputs a control change signal to the drive controller to cause the plurality of power devices other than the one or more power devices with the failure sign detected to drive the load.

### Advantageous Effects of Invention

The present invention enables providing a drive device capable of diagnosing a failure sign, the drive device having functions of diagnosing the failure sign of a power device; performing load drive control by restricting operation of the power device with the failure sign or by excluding the power device; and suppressing shortening of a replacement cycle of the power device.

### BRIEF DESCRIPTION OF DRAWINGS

FIG. 1 is a diagram illustrating an example of a configuration of a drive device according to a first embodiment.

FIG. 2 is a graph showing an example of characteristic fluctuation in a power device.

FIG. 3 is a flowchart of detection of a failure sign and output of a control change signal according to the first embodiment.

FIG. 4 is a flowchart of detection of a failure sign and output of an alarm signal according to the first embodiment.

FIG. 5 is a diagram illustrating a drive device that performs diagnosis on a characteristic sensor according to a modification of the first embodiment.

FIG. 6 is a diagram illustrating an example of a configuration of a drive device according to a second embodiment.

FIG. 7 is a diagram illustrating an example of a method for detecting a failure sign according to the second embodiment.

FIG. 8 is a diagram illustrating an example of a method for correcting a life prediction model.

FIG. 9 is a flowchart for outputting a control change signal and an alarm signal depending on a remaining life.

FIG. 10 is a diagram illustrating a configuration for notifying a remaining life as real time based on an operation history.

FIG. 11 is a diagram illustrating an example of a configuration of a vehicle according to a third embodiment.

FIG. 12 is a flowchart of a latent diagnosis method according to the third embodiment.

FIG. 13 FIG. 12 is a flowchart of a latent diagnosis method according to the third embodiment.

### DESCRIPTION OF EMBODIMENTS

Hereinafter, embodiments of the present invention will be described with reference to the accompanying drawings.

The embodiments described below enable an alarm to be issued in a form of a notification of component replacement or the like by accurately detecting a variation from an initial characteristic for a functional unit included in a semiconductor component mounted on a vehicle to determine that there is a failure sign when the amount of the variation of the characteristic increases. Then, mounting a mechanism for correcting a functional unit enables a period until component replacement to be further extended to reduce the number of times of replacement, thereby reducing cost.

### EMBODIMENTS

### First Embodiment

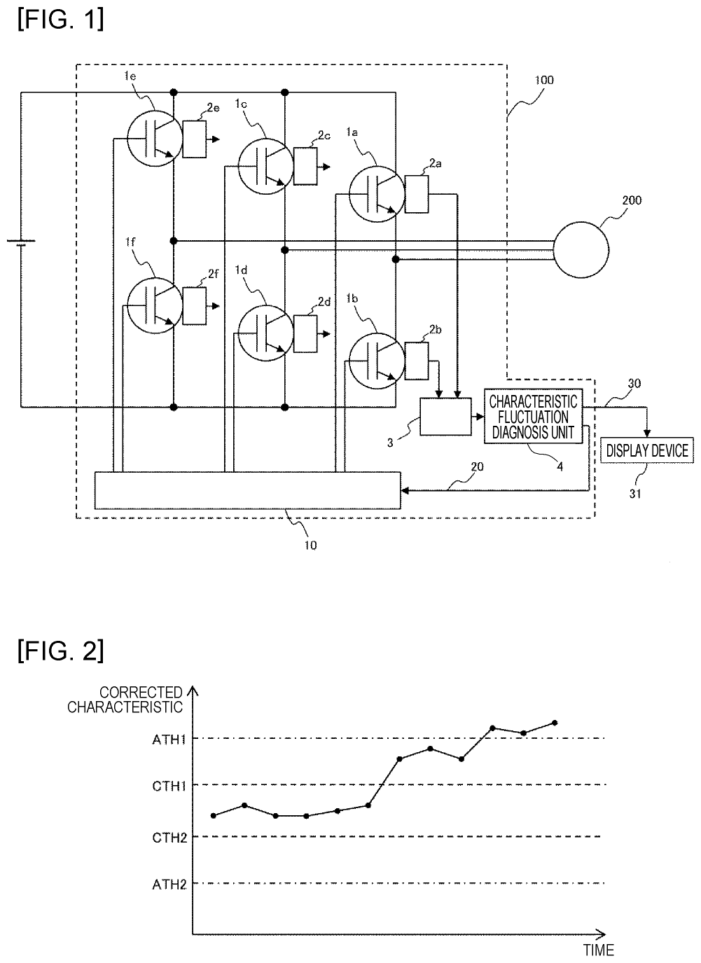

FIG. 1 is a diagram illustrating a configuration of a drive device 100 according to a first embodiment of the present invention. The drive device 100 illustrated in FIG. 1 is equipped with a plurality of power devices 1a to 1f having various characteristics that are measured by a plurality of characteristic sensors 2a to 2f disposed corresponding to the power devices 1a to 1f, respectively, and then results of the measurement are held as time series data.

Then, based on the time-series data held, it is determined whether there is a sign that a characteristic of each of the power devices 1a to 1f fluctuates over time. Consequently, a failure sign of each of the power devices 1a to 1f is detected, and control of the drive device 100 is changed according to a state of the detection to reduce a frequency of component replacement of the drive device 100 or the power devices 1a to 1f. When the characteristic of each of the power devices 1a to 1f further fluctuate from the time when the failure sign is detected, an alarm for prompting component replacement to a user is issued.

The drive device 100 according to the first embodiment of the present invention is used to drive a motor 200 illustrated as an example of a load, and converts a DC power supply into a three-phase AC signal to drive the motor 2 by vector control to convert the AC signal into a rotational force. A control method related to driving of the motor 200 as a load is already widely known, so that details thereof are not described herein.

The drive device 100 according to the first embodiment of the present invention includes the plurality of power devices 1a to 1f, a drive controller 10 that transmits a signal for controlling an electrical operation of each of the plurality of power devices 1a to 1f to the corresponding one of the power devices 1a to 1f, the plurality of characteristic sensors 2a to 2f disposed corresponding to the power devices 1a to 1f, respectively, for sensing (detecting) characteristics of the corresponding power devices 1a to 1f, and a sensing result holder (detection result holder) 3 that holds detection results as time-series data, the detection results being acquired by sensing the characteristics of the power devices 1a to 1f periodically or at a predetermined timing using the characteristic sensors 2a to 2f, respectively.

The drive device 100 further includes a characteristic fluctuation diagnosis unit 4 that refers to the time-series data on the characteristics of the power devices la to 1f held in the sensing result holder 3 to diagnose that a characteristic of each of the power devices 1a to 1f fluctuates over time, and that then transmits a control change signal 20 to the drive controller 10, and outputs an alarm signal 30.

Although the plurality of power devices 1a to 1f and the plurality of characteristic sensors 2a to 2f are described here with the numbers in combination using numbers and lower case letters, it is defined herein that the power devices 1a to 1f and the characteristic sensors 2a to 2f having the same lower case letters at the end correspond to each other when the characteristics are acquired. That is, characteristics to be monitored by the characteristic sensor 2a are herein characteristics of the power device 1a, for example.

Examples of the characteristics of the power devices 1a to 1f monitored by the characteristic sensors 2a to 2f, respectively, include not only electrical characteristics such as voltage, current, and frequency, characteristics of environmental factors, such as temperature (temperature near the power devices 1a to 1f), but also other characteristics.

The voltage, the current, the frequency, and the temperature may be intermittently measured for a predetermined period to calculate a time rate of change that may be held in the sensing result holder w as with the characteristics of each of the power devices 1a to 1f. Additionally, the characteristics may be acquired by the characteristic sensors 2a to 2f for all of the characteristics described above, or some of the characteristics in a selective manner.

The characteristics of the power devices 1a to 1f can vary depending on operation states such as power supply voltage, temperature, control contents of load drive, and phase information in drive control. Thus, the characteristics of the power devices 1a to 1f monitored by the characteristic monitors 2a to 2f, respectively, are desirably corrected based on the operation states described above, and characteristics obtained by correcting the sensed characteristics of each of the power devices 1a to 1f are referred to as corrected characteristics in the present invention.

The corrected characteristics are preferably obtained by reflecting pure characteristics of the power devices 1a to 1f after eliminating fluctuation due to the operation states described above, and error rates from expected values of the characteristics of the power devices 1a to 1f in the operation states at the time of monitoring the characteristics are preferably used, for example. Alternatively, values calculated by other methods may be used.

An example of a method for diagnosing characteristic fluctuations of the power devices 1a to 1f will be described.

FIG. 2 is a graph plotting values of the corrected characteristics on the vertical axis and time on the horizontal axis for one of the power devices 1a to 1f.

FIG. 2 shows data points plotted laterally each of which corresponds to one of the corrected characteristics held in time series. For diagnosing the characteristic fluctuation, two sets of thresholds are provided including a first sets of control thresholds CTH1 and CTH2 for detecting temporal fluctuation of the corrected characteristics and performing feedback to control contents of the drive device 100. Another set of thresholds includes alarm thresholds ATH1 and ATH2 for outputting an alarm of a warning for notifying the drive device 100 of information indicating that replacement is necessary when the characteristic fluctuation further progresses.

In the first embodiment, the control threshold CTH1 and the alarm threshold ATH1 are defined as thresholds for detecting when corresponding one of the corrected characteristics rises, and the control threshold CTH2 and the alarm threshold ATH2 are defined as thresholds for detecting when the corresponding one of the corrected characteristics falls.

The characteristic fluctuation diagnosis unit 4 has functions of: reading the time-series data on the corrected characteristics of each of the power devices 1a to 1f held in the sensing result holder 3; calculating the amount of characteristic fluctuation by a statistical method or machine learning; determining whether the corrected characteristics of the power devices 1a to 1f sensed (detected) by the characteristic sensors 2a to 2f, respectively, are within a range of the control thresholds or the alarm thresholds described above; and detecting a failure sign.

A range from the control threshold CTH2 to the control threshold CTH1 inclusive is defined as a control threshold range, and a range greater than the control threshold CTH1 and equal to or smaller than the alarm threshold ATH1 and a range smaller than the control threshold CTH2 and equal to or larger than the alarm threshold ATH2 are each defined as an alarm threshold range. The alarm threshold ranges are wider than the control threshold range.

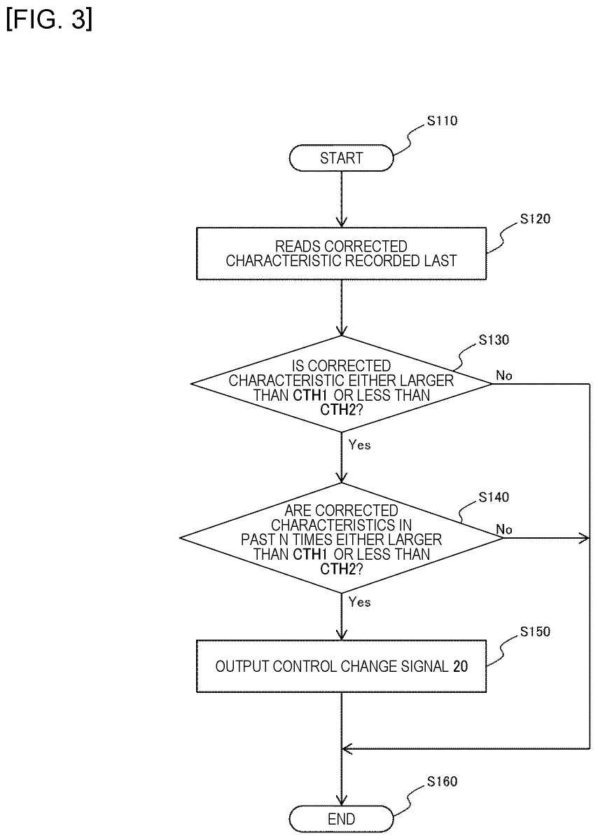

FIG. 3 is a diagram illustrating an example of a flowchart according to a method for determining characteristic fluctuation of each of the power devices 1a to 1f using corrected characteristics and outputting a control change signal to the drive controller 10.

Although the flowchart of FIG. 3 is illustrated for one of the power devices 1a to 1f, it is also applicable to other power devices mounted on the drive device 100.

First, a determination flow is started in step S110, and then the characteristic fluctuation diagnosis unit 4 reads data recorded last among the time-series data on the corrected characteristics of each of the power devices 1a to 1f held in the sensing result holder 3 in step S120. This data, i.e., a value of the latest corrected characteristic of one of the characteristics of each of the power devices 1a to 1f is compared with the control threshold CTH1 or the control threshold CTH2 in step S130. When the value of the corrected characteristic is either larger than the control threshold CTH1 or smaller than the control threshold CTH2, processing proceeds to step S140. When the value of the corrected characteristic is in the range from the control threshold CTH2 to the control threshold CTH1 inclusive in step 130, the processing proceeds to step S160 and the flowchart ends.

With reference to the corrected characteristic data for past N times (N is a natural number) from the latest one in step S140, it is determined whether the data for the past N times all exceed the control threshold CTH1 or all are less than the control threshold CTH2 (whether the amount of characteristic fluctuation has reached outside the control threshold range). When it is determined that the amount of characteristic fluctuation has reached outside the control threshold range, it is determined that the characteristics of corresponding one of the power devices 1a to 1f have fluctuated, thereby detecting a failure sign.

When the failure sign is detected in step S140, the processing proceeds to step S150, and the control change signal 20 for diagnosing characteristic fluctuation and changing a control method of the drive device 100 is output.

When the data for past N times includes data equal to or less than the control threshold CTH1 or data less than the control threshold CTH2 in step S140, the processing proceeds to step S160 and the flowchart ends.

Although the example illustrated in FIG. 3 determines the characteristic fluctuation when all the corrected characteristic data exceeds the control threshold CTH1 or all the corrected characteristic data are less than the control threshold CTH2 continuously N times, it does not matter even when a determination method is optimized by machine learning or the like, in which the number of consecutive times and an appearance pattern are combined.

The determination method can be rewritten from outside after operation time of the drive device 100.

Although the method for determining the characteristic fluctuation of each of the power devices 1a to 1f has been described above, output of the alarm signal 30 is determined when the corrected characteristics of each of the power devices 1a to 1f further fluctuates as the operation time of the drive device 100 elapses.

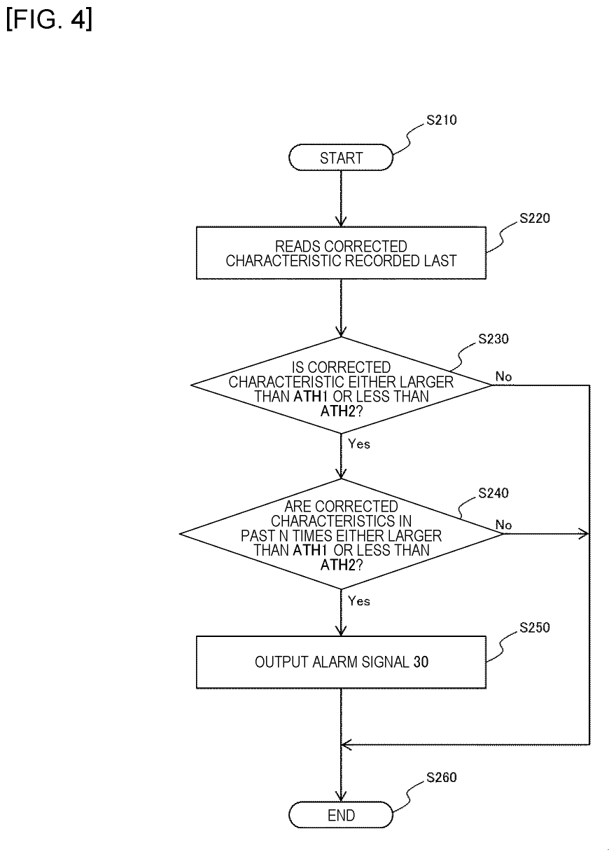

FIG. 4 is a flowchart illustrating a method for determining the characteristic fluctuation of each of the power devices 1a to 1f using corrected characteristics and outputting the alarm signal 30.

The flowchart illustrated in FIG. 3 is different from the flowchart illustrated in FIG. 4 in that thresholds in steps S230 (corresponding to step S130 in FIG. 3) and S240 (corresponding to step S140 in FIG. 3) illustrated in FIG. 4 are defined as the alarm threshold ATH1 and the alarm threshold ATH2, and a signal to be output in step S250 (corresponding to step S150 in FIG. 3) is defined as the alarm signal 30.

Operation in the flowchart of FIG. 4 may be described by replacing the control threshold CTH1 with the alarm threshold value ATH1, the control threshold value CTH2 with the alarm threshold value ATH2, and the control change signal 20 with the alarm control signal 30 in the operation in the flowchart of FIG. 3 described above.

The alarm signal 30 is output to a display device 31 installed outside the drive device 100 to display a warning display on the display device 31.

The control thresholds CTH1 and CTH2 and the alarm thresholds ATH1 and ATH2 may be set in advance prior to the operation of the drive device 100, or may be set by communicating with the outside of the drive device 100 to perform machine learning in a server at a communication destination, and reading back optimized values.

When data on the corrected characteristics across the control thresholds CTH1 and CTH2, and the alarm thresholds ATH1 and ATH2 appears, the data may be considered to be determined by a criterion such as a predetermined number of times of continuous appearances of the data, a predetermined number of times or more of appearances of the data in the latest N times regardless of continuous or discontinuous, or the like.

This criterion may be set in advance as in the setting of the thresholds described above, or may be read back from the outside later.

Operation of accumulating and storing data in time series leads to increase in the amount of data, so that a method for reducing the number of pieces of data in the determination above using the latest data is also conceivable, the method being configured to perform treatment such as averaging past data out of data to be determined or re-recording the data with a value and frequency as a histogram. The sensing result holder 3 in the present embodiment internally includes a data holding method and a management method that can also be appropriately selected.

The corrected characteristics can be stored in a storage device such as a server to which information is transmitted by wireless communication, and can be used as examination data on an algorithm of machine learning or determination of characteristic fluctuation. This case enables providing more optimal operation by rewriting a threshold for determination of the characteristic fluctuation for each of the power devices 1a to 1f of the drive device through wireless communication to optimize the control threshold and the alarm threshold for the characteristic fluctuation diagnosis for each of the power devices 1a to 1f in the drive device 100 according to a result of machine learning performed by the server.

Next, contents of change in control of the drive device 100 will be described, the control being changed when it is determined that each of the power devices 1a to 1f indicates a failure sign, i.e., there is a sign of fluctuation when the characteristics of each of the power devices 1a to 1f are viewed from a temporal viewpoint.

The characteristic fluctuation of each of the power devices 1a to 1f, which progresses when the drive device 100 is operated, is assumed to vary among the power devices 1a to 1f even in the same drive device 100.

A usable period of the entire drive device 100 is equal to a usable period of all the power devices 1a to 1f. The present invention enables extending the usable period of the entire drive device 100 by reducing an operation rate of one of the power devices 1a to 1f, in which a failure sign is detected, and changing control of the drive device 100 to relatively delay a progress of characteristic fluctuation of the power device in which the failure sign is detected as compared with the other power devices.

The power device power devices 1a to 1f are at least disposed in each phase of three-phase alternating current such that one power device is disposed close to a power supply (on an upper arm) and one power device is disposed close to the ground (on a lower arm).

To drive the motor 200 described as a load in the present invention, two phases out of the three phases need to operate. Thus, a unit of power devices to be excluded from the control of the drive device 100 is two power devices including the upper arm and the lower arm in charge of load drive.

When a failure sign is detected in one power device, operation of a drive phase in charge of the power device is stopped, and the load drive is changed to load drive using the remaining two phases. Then, a period of the stop desirably can be switched in accordance with torque required for the motor 200, i.e., a current value necessary for the load drive.

More specifically, the drive of the phase to which the power device belongs is stopped increasing relatively a stop period of the power device under a load condition where the required torque relatively decreases.

When a failure sign is detected in a plurality of power devices in a plurality of control phases, a phase to be excluded from the drive control is changed in a time division manner, and the plurality of power devices is controlled causing deterioration to progress uniformly.

When characteristic fluctuation that is a failure sign occurs in a characteristic of the power device constituting the drive device 100, using the drive device 100 described in the first embodiment allows the characteristic fluctuation to be detected to transmit the control change signal 20 to the drive controller 10, thereby changing a control method of the drive device 100.

Consequently, a period until the alarm signal 30 is output can be increased as compared with when the control method of the drive device 100 is not changed.

When a warning is displayed on the display device 31, a user of the drive device 100 takes measures such as component replacement after recognizing that the alarm signal 30 is output. Then, when a period until the alarm signal 30 is output is extended according to the present invention, a temporal interval of the component replacement is increased, and thus a replacement frequency can be reduced.

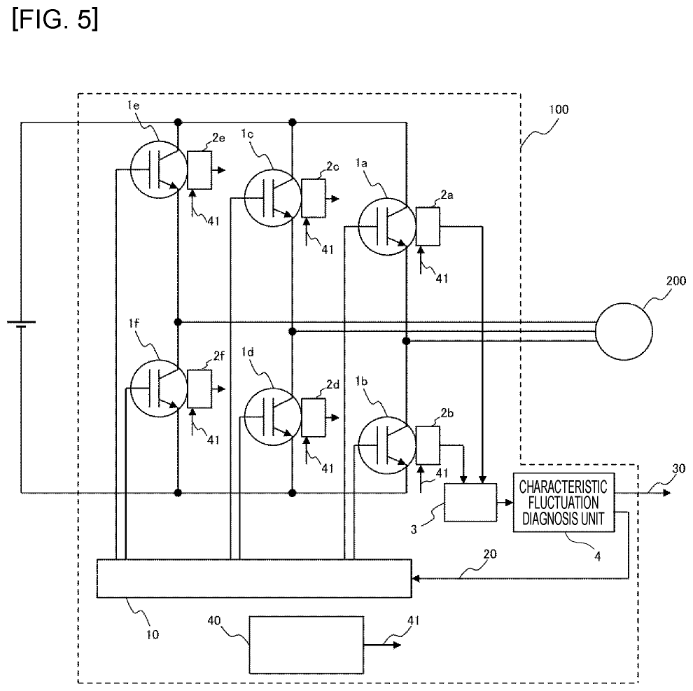

Next, a modification of the first embodiment will be described with reference to FIG. 5.

FIG. 5 is a diagram illustrating a configuration of a drive device 100 according to a modification of the first embodiment. The drive circuit 100 in FIG. 5 includes a self-diagnosis controller 40 that instructs self-diagnosis of the plurality of characteristic sensors 2a to 2f in addition to the configuration illustrated in FIG. 1.

The modification of the first embodiment is the drive device 100 capable of diagnosing a failure sign of each of the characteristic sensors 2a to 2f by detecting the amount of variation by self-diagnosis when a temporal variation occurs in accuracy of detection values themselves of the characteristic sensors 2a to 2f.

For example, the drive device 100 having the configuration illustrated in FIG. 5 further includes the self-diagnosis controller 40 for transmitting a signal for instructing the characteristic sensors 2a to 2f to perform self-diagnosis. The self-diagnosis controller 40 is equipped with a circuit that generates a reference signal 41 with predetermined voltage, current, or frequency to be used periodically or for self-diagnosis of the characteristic sensors 2a to 2f, and the reference signal 41 is output to each of the characteristic sensors 2a to 2f to diagnose characteristic detection accuracy of the corresponding one of the characteristic sensors 2a to 2f. The reference signal 41 described above is to be operated only when the self-diagnosis of the characteristic sensors 2a to 2f is performed, and is stopped operating for other than the self-diagnosis.

As with the characteristics of the power devices 1a to 1f, a method of control is also conceivable in which errors of the characteristic sensors 2a to 2f obtained by self-diagnosis are also held in the sensing result holder 3, and the errors of the characteristic sensors 2a to 2f are taken into consideration in characteristic sensing results of the power devices 1a to 1f. Alternatively, when the errors of the characteristic sensors 2a to 2f show a tendency to fluctuate over time, a failure sign can be detected using a threshold as in the power devices 1a to 1f, and an alarm for a component replacement notification can be set on a device similar to the display device 31 illustrated in FIG. 1.

The reference signal for self-diagnosis is output only at the time of the self-diagnosis, so that an activation rate of the reference signal is suppressed lower than that of other circuits and devices in the drive device 100. Thus, characteristic fluctuation of the reference signal itself can be ignored for other circuits and devices.

As described above, the first embodiment enables providing the drive device 100 capable of diagnosing a failure sign of each of the power devices 1a to 1f mounted, and reducing frequency of component replacement by collecting and optimizing data on the drive device 100 existing in the market and optimizing a diagnosis threshold of the failure sign. Additionally, cost can be reduced by reducing the frequency of component replacement to reduce the number of times of the component replacement.

That is, the first embodiment of the present invention enables providing the drive device 100 capable of: diagnosing a failure sign of each of the power devices 1a to 1f; performing load drive control by restricting operation of corresponding power devices 1a to 1f with the failure sign or by excluding the corresponding power devices 1a to 1f; and suppressing shortening of a replacement cycle of the power devices 1a to 1f.

### Second Embodiment

Next, a second embodiment of the present invention will be described.

The second embodiment of the present invention is configured as follows: various characteristics related to a plurality of power devices 1a to 1f mounted on a drive device 100 are measured by a plurality of characteristic sensors 2a to 2f disposed corresponding to the power devices 1a to 1f, respectively; the amount of stress represented by the product of each measurement result and a measurement time interval is accumulated as time-series data; and a remaining life of each of the power devices 1a to 1f is determined whether to fall below a predetermined threshold based on the amount of stress accumulated.

The drive device 100 will be described in which the configuration above enables the drive device 100 to be capable of; reducing frequency of component replacement of the drive device 100 or the power devices 1a to 1f by detecting a failure sign of each of the power devices 1a to 1f and changing control of the drive device 100 corresponding to a detection state; and issuing an alarm for prompting a user to replace a component when the remaining life of each of the power devices 1a to 1f further fluctuates.

The second embodiment will be described in which thermal stress serves as the amount of stress, for example, and the thermal stress is expressed by the product of temperature measured by the characteristic sensors 2a to 2f and a measurement time interval.

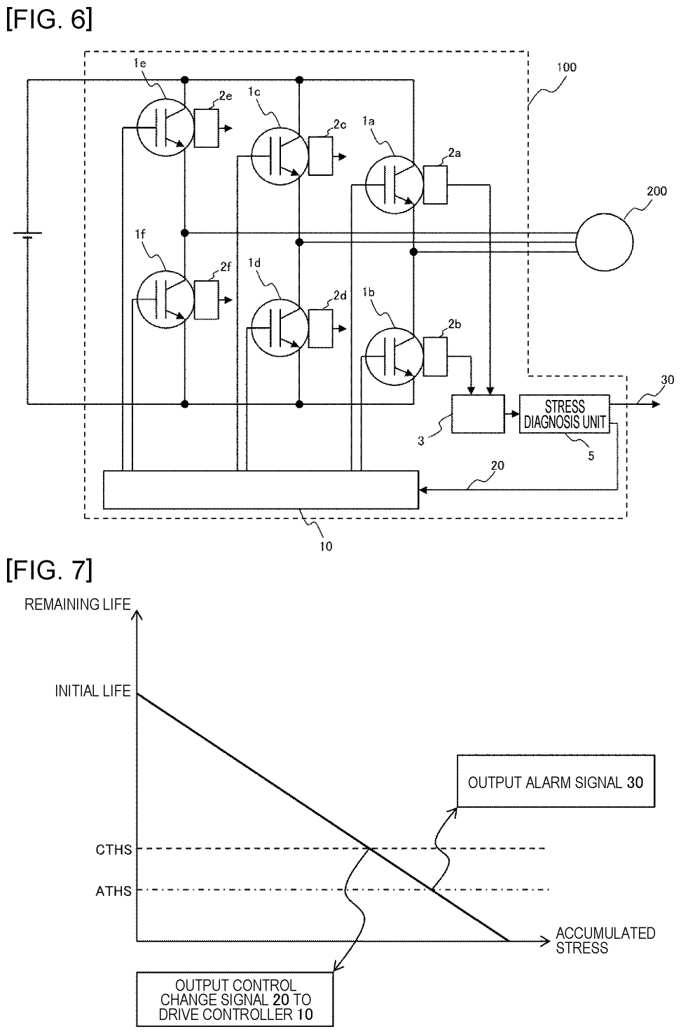

FIG. 6 is a diagram illustrating the drive device 100 according to the second embodiment of the present invention. The drive device 100 according to the second embodiment is different from the configuration illustrated in the drive device 100 according to the first embodiment of the present invention illustrated in FIG. 1 in that a stress diagnosis unit 5 is provided instead of the characteristic fluctuation diagnosis unit 4 according to the first embodiment, the stress diagnosis unit 5 being provided for calculating accumulated stress on the power devices 1a to 1f to determine their remaining lives based on accumulated values of characteristics of the power devices 1a to 1f acquired by the characteristic sensors 2a to 2f, respectively, the accumulated values being held in a sensing result holder 3.

An example of a method for performing stress diagnosis using the accumulated stress of the power devices 1a to 1f will be described.

FIG. 7 is a diagram schematically illustrating a relationship between accumulated stress applied to each of the power devices 1a to 1f and a remaining life of the corresponding one of the power devices 1a to 1f. FIG. 7 shows an intercept on the vertical axis that indicates a remaining life at the start of operation of the drive device 100, and an intercept on the horizontal axis that indicates the amount of accumulated stress at the time when the remaining life has expired, i.e., at the time when each of the power devices 1a to 1f has failed.

Usually, a reliability test and a durability test are performed in a development stage of a semiconductor element constituting each of the power devices 1a to 1f before the drive device 100 starts operation, and life prediction of each of the power devices 1a to 1f is estimated from the test results, and the vertical axis intercept and the horizontal axis intercept, described above, and a line segment connecting the intercepts are determined.

In a state immediately after the drive device 100 starts the operation, accumulated thermal stress of each of the power devices 1a to 1f may be regarded as 0, and the remaining life of each of the power devices 1a to 1f at this time is substantially equal to that in an initial state (initial life).

Temperature at which the drive device 100 operates is sensed by the characteristic sensors 2a to 2f for the power devices 1a to 1f, respectively, and the product of the temperature and time is accumulated as thermal stress in the sensing result holder 3.

The stress diagnosis unit 5 stores the relationship between the amount of accumulation of the thermal stress and the remaining life illustrated in FIG. 7 as numerical information, and the remaining life of each of the power devices 1a to 1f is calculated from the amount of thermal stress recorded in the sensing result holder 3. At that time, two types of threshold, which are a control threshold CTHS and an alarm threshold ATHS, and the remaining life are compared, and when the remaining life is below each threshold, operation below is performed.

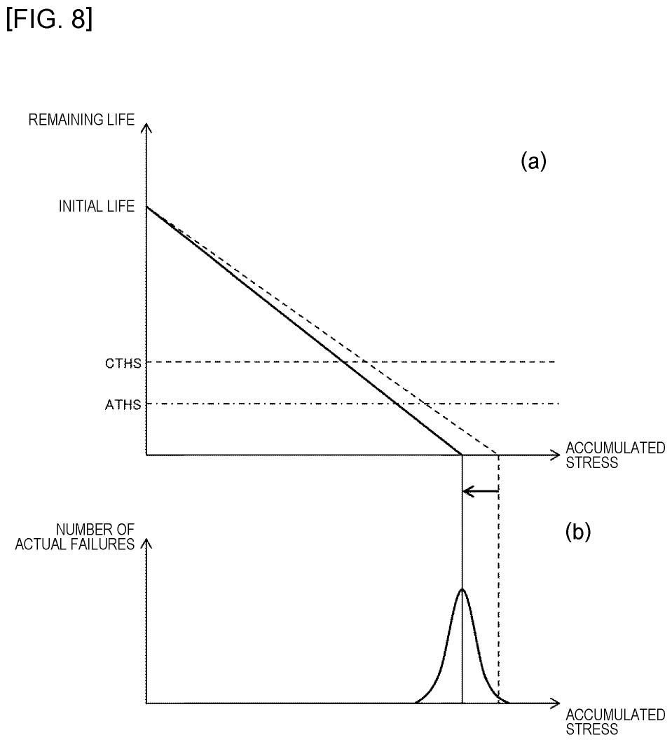

FIG. 8 is a diagram illustrating a method for correcting a remaining life prediction model of each of the power devices 1a to 1f.

FIG. 8 includes a part (a) illustrating a broken line that is a remaining life model determined from results of the reliability test and the durability test described above.

FIG. 8 includes a part (b) illustrating a waveform that is obtained by taking a frequency distribution for the amount of accumulated thermal stress at the time when each of the power devices 1a to 1f is actually used until failure for a plurality of drive devices 100 on the market.

When the amount of stress at the time of occurrence of actual failure is compared with that in a remaining life prediction model at an initial stage, actual failure timing does not necessarily match with that in the remaining life prediction model. Thus, a life prediction model is corrected based on accumulated data. Specifically, the highest probability of occurrence of the actual failure is for thermal stress.

That is, the life prediction model is corrected with a new horizontal intercept that is the amount of accumulated stress with a maximum number of actual failures. FIG. 8 indicates the remaining life prediction model after the correction with a solid line.

The drive device 100 collected and replaced from the market may be operated until an actual failure occurs in each of the power devices 1a to 1f to collect data on the relationship between the accumulated thermal stress and the remaining life of the corresponding one of the power devices 1a to 1f. This collection of the data is considered to be able to contribute to improvement of accuracy of life prediction.

Next, a method will be described in which the control change threshold CTHS and the alarm threshold ATHS are set for the remaining life that decreases with increase in the accumulated stress, and a control change signal 20 for changing the control of the drive device 100 and a component replacement alarm 30 are output when the remaining life falls below the corresponding thresholds.

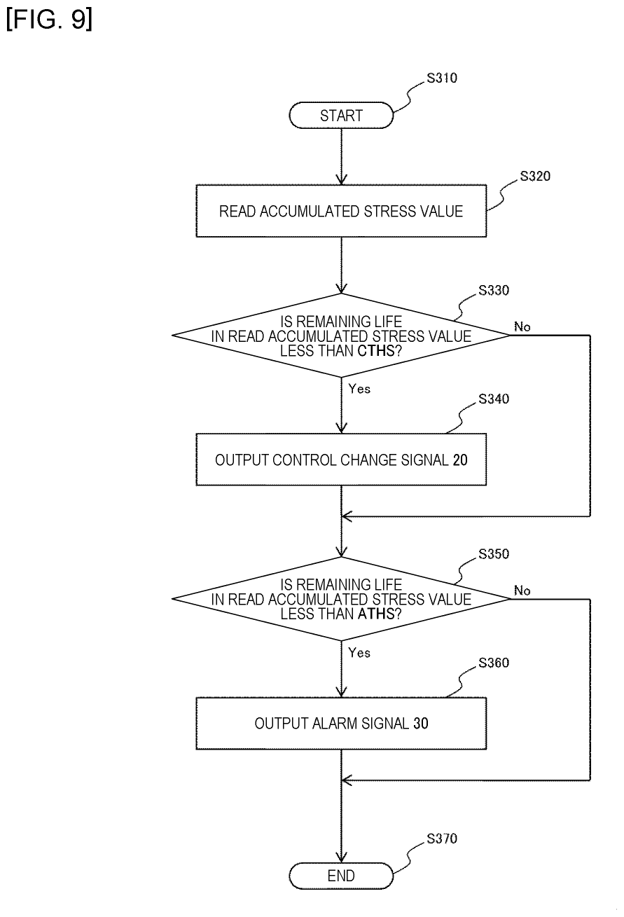

FIG. 9 is a flowchart related to a method for outputting the control change signal 20 for changing the control of the drive device 100, and the component replacement alarm 30.

First, a determination flow is started in step S310, and then the stress diagnosis unit 5 reads an accumulated stress value of each of the power devices 1a to 1f held in the sensing result holder 3 in step S320.

The remaining life corresponding to the accumulated stress value having been read is compared with the control threshold value CTHS in step S330.

When the remaining life is less than the control threshold CTHS, processing proceeds to step S340, and the control change signal 20 is output.

When the remaining life is larger than the control threshold CTHS in step S330, the processing proceeds to step S350, and the remaining life is compared with the alarm threshold ATHS. When the remaining life is less than the alarm threshold ATHS, the processing proceeds to step S360, and the alarm signal 30 is output.

Next, when the remaining life is equal to or more than the alarm threshold ATHS in step S350, the processing proceeds to step S370, and the flowchart ends.

Accumulation pace of the thermal stress, i.e., pace of progress in the horizontal axis direction in FIG. 8, varies depending on how the thermal stress is applied. Even when two use manners with the same operation time are assumed, for example, the amount of accumulation of accumulated stress in each use manner is different when environmental temperature is different.

In view of this point, information on how to use the drive device 100 is used to determine the remaining life using the accumulated stress and further replace the remaining life with real time, and this information may be not only accumulated in the drive device 100 but also transmitted and managed by an external server through wireless communication or the like.

For example, when the drive device 100 is operated in the market, data on correspondence between the accumulated thermal stress and the remaining life of each of the power devices 1a to 1f in the drive device 100 is accumulated. Correcting a life prediction model of a device, which is determined by the reliability test and the durability test at the initial stage, based on these data enables life prediction under conditions closer to actual operation, so that accuracy of the life prediction in the drive device 100 can be improved. The control threshold CTHS and the alarm threshold ATHS each also can be set to an optimum value by being similarly read back and reset.

The control change and the alarm output based on the remaining life described in the second embodiment may be output in combination with the method based on the characteristic fluctuation described in the first embodiment at a point of time when conditions are earlier satisfied in any one of the methods, or a signal may be output when the conditions are satisfied in both the methods.

Next, contents of the control change of the drive device 100 when the remaining life of each of the power devices 1a to 1f decreases to lead determination of a failure sign in the second embodiment will be described. The control change is similar in a concept and contents to those of the first embodiment of the present invention, so that further detailed description thereof is duplicated and thus is not described. A difference from the first embodiment of the present invention is a ground of the failure sign diagnosis, the ground being based on a temporal characteristic fluctuation of each of the power devices 1a to 1f or based on decrease in the remaining life of each of the power devices 1a to 1f due to accumulated stress.

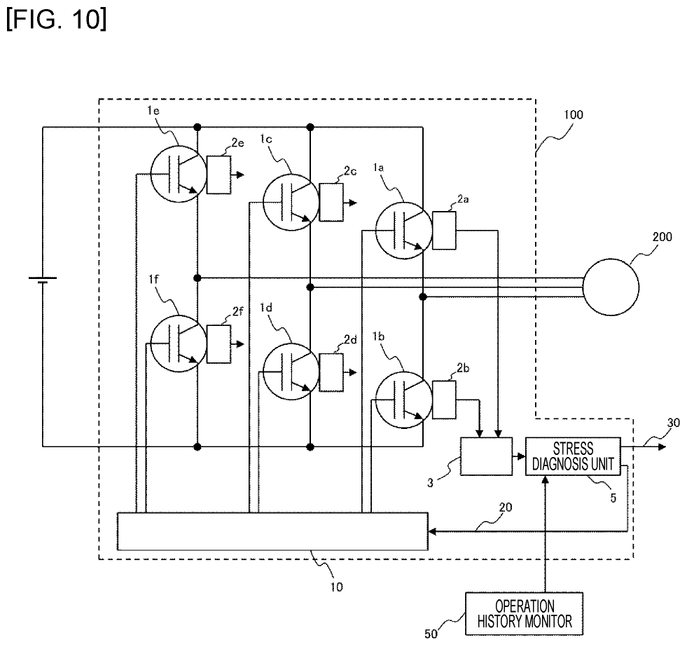

Next, a method will be described with reference to FIG. 10 in which pace of increase in an accumulated thermal stress value is calculated and checked against the life prediction model and the remaining life to predict timing at which the alarm is issued and notify the user of the predicted timing.

FIG. 10 illustrates an operation history monitor 50 that is further provided to input operation information on the drive device 100 to the stress diagnosis unit 5 of the drive device 100. Considerable examples of the input operation information on the drive device 100 include an operation time per unit time, a control condition, and a temperature change. According to the examples, the operation history monitor 50 has an object of calculating the amount of stress increase per unit time. From a relationship between the amount of stress increase per unit time and the remaining life, an actual failure time can be predicted.

Similarly, timing at which the remaining life reaches the control threshold CTHA or the alarm threshold ATHS can be similarly predicted. When the timing is transmitted to the outside of the drive device 100, the display device 31 illustrated in FIG. 1 and provided to the drive device 100 can visually notify the user, for example.

That is, convenience is improved in that the user can know a rough time before occurrence of an alarm or a failure.

As described above, the second embodiment of the present invention is configured as follows: various characteristics related to the plurality of power devices 1a to 1f mounted on the drive device 100 are measured by the plurality of characteristic sensors 2a to 2f disposed corresponding to the power devices 1a to 1f, respectively; the amount of stress represented by the product of each measurement result and a measurement time interval is accumulated as time-series data; and a remaining life of each of the power devices 1a to 1f is determined whether to fall below a predetermined threshold based on the amount of stress accumulated.

The configuration above enables providing the drive device 100 capable of; reducing frequency of component replacement of the drive device 100 or the power devices 1a to 1f by detecting a failure sign of each of the power devices 1a to 1f and changing control of the drive device 100 according to a detection state; and issuing an alarm for prompting a user to replace a component when the remaining life of each of the power devices 1a to 1f further fluctuates.

### Third Embodiment

Next, a third embodiment of the present invention will be described.

In the third embodiment of the present invention, a vehicle equipped with a drive device 100 will be described, the drive device 100 being capable of: issuing a notification of component replacement at appropriate timing by detecting a failure sign by detection of characteristic fluctuation in each of power devices 1a to 1f mounted on the drive device 100 and calculating accumulated stress to calculate a remaining life of each of the power devices; and reducing frequency of component replacement.

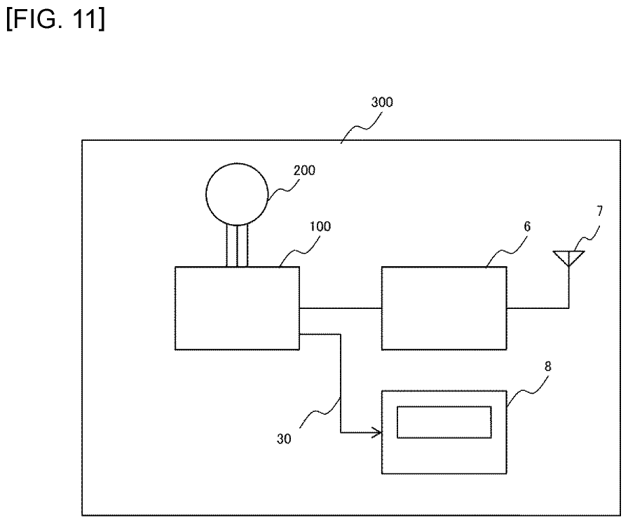

FIG. 11 is a diagram illustrating a configuration of a vehicle 300 according to the third embodiment of the present invention.

FIG. 11 illustrates the vehicle 300 including a drive device 100, a motor 200, a wireless communication module 6, an antenna 7, and a display device 8. The drive device 100 may be the one shown in the first embodiment or the one shown in the second embodiment.

The wireless communication module 6 and the antenna 7 are in charge of control for performing wireless communication between the drive device 100 and a server (not illustrated) disposed outside the vehicle 300. The server is equipped with a module for machine learning, and calculates data to be recursively calculated based on data transmitted from the drive device 100 and to be transmitted to the drive device 100 again.

Considerable examples of the data transmitted from the drive device 100 to the server, the examples being according to the present specification, include a control threshold CTH1, CTH2, or CTHS, an alarm threshold ATH1, ATH2, or ATHS, accumulated thermal stress data at the time when each of the power devices 1a to 1f reaches an actual failure, corrected characteristics accumulated in time series in a sensing result holder 3 of the drive device 100, and statistical data on traveling of the vehicle 300.

Considerable examples of a target with which the server communicates include not only the single drive device 100, but also the drive device 100 mounted on each of a plurality of different vehicles 300 operating similarly in the market.

Considerable examples of the data transmitted from the server to the drive device 100 include the control threshold CTH1, CTH2, or CTHS recalculated based on the data transmitted from the drive device 100, the alarm threshold ATH1, ATH2, or ATHS, and a life prediction model of the power devices 1a to 1f.

The characteristic fluctuation diagnosis unit 4 in the first embodiment and the stress diagnosis unit 5 in the second embodiment can correct a range of the control threshold and the remaining life with reference to the control threshold CTH1, CTH2, or CTHS, the alarm threshold ATH1, ATH2, or ATHS, and the life prediction model of the power devices 1a to 1f, received from the server.

Using the present configuration enables correcting and optimizing the thresholds and determination criteria for diagnosis and control of the contents described in the first embodiment and the second embodiment of the present invention based on mass data in the market.

The server includes a machine learning module capable of: estimating operation environment from data obtained from the drive device 100; and individually transmitting a recalculation result corresponding to the operation environment to the drive device 100 based on data on another vehicle 300 operating in a similar environment, for example. This configuration enables improving accuracy of the control change threshold CTH1, CTH2, or CTHS, the alarm threshold ATH1, ATH2, or ATHS, and the life prediction model of the drive device 100 in a similar operation environment.

Next, timing of performing diagnosis in the drive device 100 mounted on the vehicle 300 will be described.

The first embodiment and the second embodiment each describe timing of acquiring characteristics, the timing being during operation of the drive device 100, so that an acquired characteristic value needs to be corrected corresponding to operation conditions.

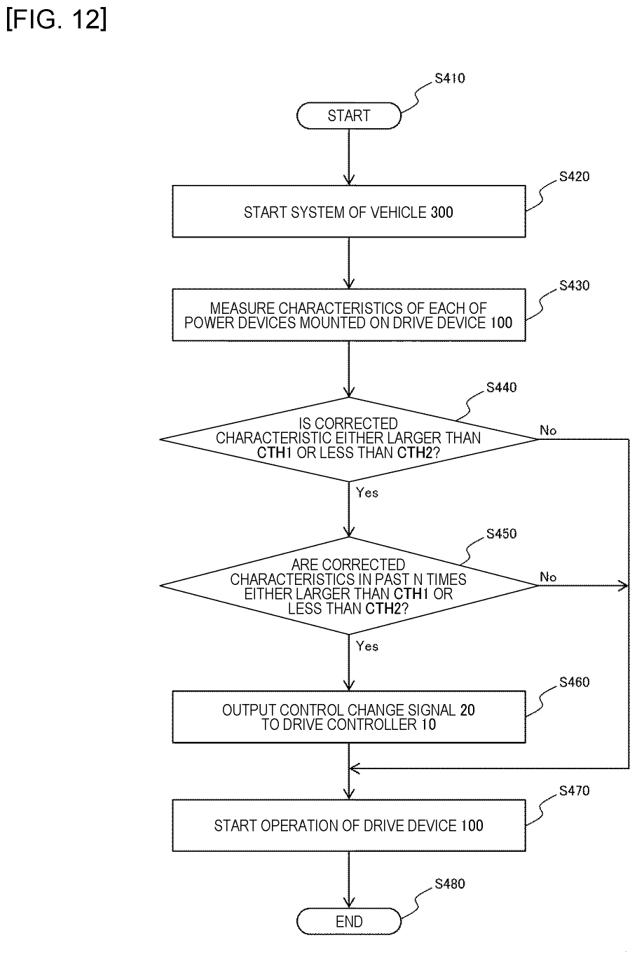

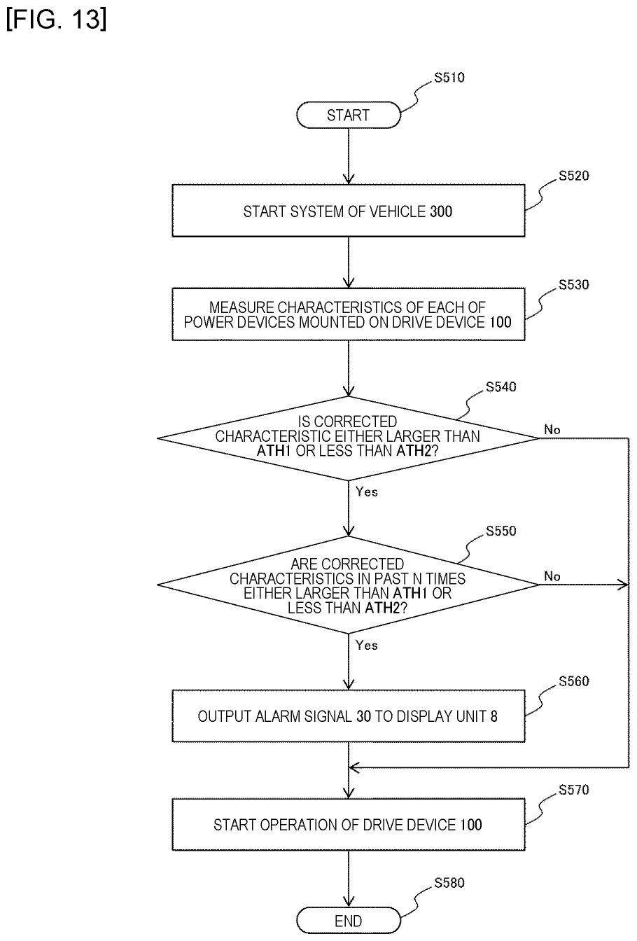

The third embodiment will be described with reference to FIGS. 12 and 13 each of which illustrates a flowchart of a sequence of performing latent diagnosis in an initial state before the drive device 100 starts operation after a system of the vehicle 300 is started.

FIG. 12 is a diagram illustrating a flow of the latent diagnosis for detecting whether characteristic fluctuation exists in each of power devices 1a to 1f mounted on the drive device 100 as a failure sign before the drive device 100 starts the operation after the system of the vehicle 300 is started.

Similarly, FIG. 13 is a diagram illustrating a flow of the latent diagnosis for outputting characteristic fluctuation as an alarm of component replacement.

In FIG. 12, after the flow stars in step S410, the system of the vehicle 300 is started in step S420. Next, characteristics of each of the power devices 1a to 1f mounted on the drive device 100 are measured in step S430.

After that, steps S440, S450, and S460 are respectively similar to steps S130, S140, and S150 (FIG. 3) described in the first embodiment, and thus detailed description thereof is not described.

The characteristics of each of the power devices 1a to 1f mounted on the drive device 100 are measured, and diagnosis of characteristic fluctuation is performed in steps S440 and S450 to detect whether a failure sign exists.

The latent diagnosis is completed by S460, and the drive device 100 starts operation such as load driving in step S470. After that, diagnosis similar to that shown in the first embodiment is performed periodically or at specific timing.

Performing the latent diagnosis enables performing diagnosis in more various situations before and after the drive device 100 stars the operation, and transmitting a diagnosis result to a server enables improving accuracy of machine learning, and eventually improving accuracy of a diagnosis threshold and a life prediction model fed back from the server.

As described above, the third embodiment enables providing a vehicle equipped with the drive device 100 will be described, the drive device 100 being capable of: issuing a notification of component replacement at appropriate timing by detecting a failure sign by detection of characteristic fluctuation in each of power devices 1a to 1f mounted on the drive device 100 and calculating accumulated stress to calculate a remaining life of each of the power devices 1a to 1f; and reducing frequency of component replacement.

Although FIG. 11 illustrates the vehicle 300 to which the present invention is applied, the present invention is also applicable to air mobility other than vehicles, for example.

The present invention is not limited to the above first, second, and third embodiments, and includes various modifications. For example, the above first, second, and third embodiments have been described in detail to describe the present invention in an easy-to-understand manner, and are not necessarily limited to those having all the described configurations.

The configuration of any one of the embodiments can be partially replaced with a configuration of another embodiment, and the configuration of the other embodiment can be added to the configuration of any one of the embodiments.

Additionally, another configuration can be added, deleted, and replaced for a part of the configuration of each of the first, second, and third embodiments.

A control line and an information line considered to be necessary for description are illustrated, and all control lines and information lines are not necessarily shown in terms of a product.

The characteristic fluctuation diagnosis unit 4 in the first embodiment and the stress diagnosis unit 5 in the second embodiment can be collectively referred to as a control change signal output unit.

### REFERENCE SIGNS LIST

1a, 1b, 1c, 1d, 1e, 1f power device
2a, 2b, 2c, 2d, 2e, 2f characteristic sensor
3 sensing result holder
4 characteristic fluctuation diagnosis unit (control signal change unit)
5 stress diagnosis unit (control signal change unit)
6 wireless communication module
7 antenna
8, 31 display device
10 drive controller
20 control change signal
30 alarm signal
40 Self-diagnosis controller
41 reference signal
50 operation history monitor
100 drive device
200 motor
300 vehicle
CTH1, CTH2, CTHS control threshold
ATH1, ATH2, ATHS alarm threshold

1. A drive device capable of failure sign diagnosis, the drive device comprising:
a plurality of power devices configured to drive a load;
a characteristic sensor configured to detect a characteristic of each of the plurality of power devices;
a sensing result holder configured to hold detection results of the plurality of power devices in time series, the detection results being acquired by the characteristic sensor;
a control signal change unit configured to detect a failure sign of each of the plurality of power devices from the detection results held in time series by the sensing result holder and output a control change signal; and
a drive controller configured to control driving of the plurality of power devices,
wherein the control signal change unit detects a failure sign of each of the plurality of power devices based on a control threshold, and
when detecting the failure sign of one or more power devices of the plurality of power devices, the control signal change unit outputs a control change signal to the drive controller to cause the plurality of power devices other than the one or more power devices with the failure sign detected to drive the load.

2. The drive device according to claim 1, wherein the control signal change unit serves as a characteristic fluctuation diagnosis unit having functions of: calculating an amount of characteristic fluctuation of each of the plurality of power devices from the detection results held in time series by the sensing result holder; and determining whether the amount of characteristic fluctuation each of the plurality of power devices has reached outside a control threshold range defined by the control threshold to detect a failure sign.

3. The drive device according to claim 2, wherein the characteristic fluctuation diagnosis unit has functions of: determining whether the amount of characteristic fluctuation has reached outside an alarm threshold range wider than the control threshold range defined by the control threshold; and outputting an alarm signal of warning when the amount of characteristic fluctuation has reached outside the alarm threshold range.

4. The drive device according to claim 1, wherein the control signal change unit serves as a stress diagnosis unit having functions of: calculating a remaining life from an amount of stress, the remaining life being an amount of characteristic fluctuation of each of the plurality of power devices, the amount of stress being represented by a product of the detection results held in time series by the sensing result holder and a measurement time interval; and determining whether the remaining life of each of the plurality of power devices is below the control threshold to detect a failure sign.

5. The drive device according to claim 4, wherein the stress diagnosis unit has function of: determining whether the remaining life reaches an alarm threshold shorter than the control threshold; and outputting a warning alarm signal when the remaining life is shorter than the alarm threshold.

6. The drive device according to claim 4, wherein the remaining life of each of the power devices is calculated by a method that is modified with reference to failure data in another drive device stored in a destination server communicated through wireless communication.

7. The drive device according to claim 2, further comprising a self-diagnosis controller that transmits a reference signal for diagnosing operation of the characteristic sensor to the characteristic sensor.

8. A vehicle comprising the drive device according to claim 1.
